(19) United States
(12) Patent Application Publication
(10) Pub. No.: US 2017/0366203 A1
(43) Pub. Date: Dec. 21, 2017

(54) HOLOGRAPHIC DATA STORAGE SYSTEM AND METHOD

(71) Applicant: FOUNDATION OF SOONGSIL UNIVERSITY INDUSTRY COOPERATION, Seoul (KR)

(72) Inventors: Jae Jin LEE, Seoul (KR); Chi Dinh NGUYEN, Seoul (KR)

(21) Appl. No.: 15/272,446

(22) Filed: Sep. 22, 2016

(30) Foreign Application Priority Data
Jun. 16, 2016 (KR) 10-2016-0075264

(51) Int. Cl. H03M 13/29; G11B 20/10; G11B 7/0065; G11B 20/18; G06F 11/10

(52) U.S. Cl. CPC H03M 13/2906; G11B 20/1833; G06F 11/1076; G11B 7/0065; G11B 20/10212

(57) ABSTRACT

Holographic data storage system and method are disclosed. The holographic data storage system includes an encoder configured to convert input data into a codeword, a storage unit configured to store the converted codeword, and a decoder configured to convert the stored codeword into output data. Here, the encoder converts the input data having 8 bits into the codeword in (5×2) matrix.

### PRIORITY

This application claims priority under 35 U.S.C. §119(a) to a Korean patent application filed on Jun. 16, 2016 in the Korean Intellectual Property Office and assigned Serial No. 10-2016-0075264, the entire disclosure of which is incorporated herein by reference.

### TECHNICAL FIELD

The present disclosure relates to holographic data storage system and method using a modulation code technique to enhance a performance of the holographic data storage system.

### BACKGROUND ART

A holographic data storage system HDS stores data in a volume of a medium unlike an optical recording storage device such as CD, DVD or BD for storing information in its surface or a hard disk drive HDD, thereby increasing sharply storage capacity. Accordingly, the holographic data storage system has been studied as the next generation optical recording storage device with a near field recording NFR or a super-resolution near-field structure SUPER_RENS.

A recording and a playing in the holographic data storage system are performed in a unit of a page, and thus a total storage capacity of the medium is determined to equal to a multiplication of a total number of bits in one page and a number of a multiplexed hologram. Since input data are written and read in a unit of a two dimensional page in a volume of the hologram, the storage capacity can be considerably increased. Moreover, a signal can be processed in the unit of the two dimensional page, and thus a transmission velocity can sharply increase.

However, the holographic data storage system has many error factors such as inter-symbol interference ISI, inter-page interference IPI and a blur between adjoining pixels, etc. Specially, two dimensional 2D ISI is a main factor for deteriorating quality of searched data. Many studies have been progressed to solve these problems. Particularly, a channel coding of original user data is one for excellent methods of reducing a two dimensional interference.

### SUMMARY

Accordingly, the invention is provided to substantially obviate one or more problems due to limitations and disadvantages of the related art. One embodiment of the invention provides holographic data storage system and method using a modulation code technique to enhance performance of the holographic data storage system.

Other features of the invention may be thought by a person in an art through following embodiments.

In one aspect, the invention provides a holographic data storage system comprising: an encoder configured to convert input data into a codeword; a storage unit configured to store the converted codeword; and a decoder configured to convert the stored codeword into output data. Here, the encoder converts the input data having 8 bits into the codeword in (5×2) matrix.

Each of a first column and a second column of the (5×2) matrix has 32 patterns, and wherein the encoder does not use a pattern [X, 1, 0, 1, X]^{T} and a pattern [X, 0, 1, 0, X]^{T} in the conversion of the codeword.

The encoder does not use a pattern [X, 0, 0, 1, 0]^{T} and a pattern [X, 1, 1, 0, 1]^{T} in the conversion of the codeword.

The encoder does not use a pattern [1, 0, 1, 1, X]^{T} and a pattern [0, 1, 0, 0, X]^{T} in the conversion of the codeword.

Each of a first column and a second column of the (5×2) matrix has 32 patterns and the encoder uses 16 patterns of the 32 patterns. Here, the 16 patterns include a pattern [0, 0, 0, 0, 0]^{T}, a pattern [0, 0, 0, 0, 1]^{T}, a pattern [0, 0, 0, 1, 1]^{T}, a pattern [0, 0, 1, 1, 0]^{T}, a pattern [0, 0, 1, 1, 1]^{T}, a pattern [0, 0, 1, 1, 0, 0]^{T}, a pattern [0, 1, 1, 1, 0]^{T}, a pattern [0, 1, 1, 1, 1]^{T}, a pattern [1, 0, 0, 0, 0]^{T}, a pattern [1, 0, 0, 0, 1]^{T}, a pattern [1, 0, 0, 1, 1]^{T}, a pattern [1, 1, 0, 0, 0]^{T}, a pattern [1, 1, 0, 0, 1]^{T}, a pattern [1, 1, 1, 0, 0]^{T}, a pattern [1, 1, 1, 1, 0]^{T} and a pattern [1, 1, 1, 1, 1]^{T}.

In another aspect, the invention provides a holographic data storage method performed by a processor, the method comprising: an encoding step of converting input data into a codeword; a storage step of storing the converted codeword; and a decoding step of converting the stored codeword into output data. Here, the encoding step includes converting the input data having 8 bits into the codeword in (5×2) matrix.

Holographic data storage system and method of the invention may enhance a performance of the holographic data storage system.

### BRIEF DESCRIPTION OF DRAWINGS

Example embodiments of the present invention will become more apparent by describing in detail example embodiments of the present invention with reference to the accompanying drawings, in which:

FIG. 1 is a view illustrating schematically a holographic data storage system HDS using the modulation code technique according to one embodiment of the invention;

FIG. 2 is a flowchart illustrating a holographic data storage method according to one embodiment of the invention;

FIG. 3 is a view illustrating a concept of an operation of the encoder according to one embodiment of the invention;

FIG. 4 to FIG. 6 are views illustrating s simulation result of holographic data storage system and method according to one embodiment of the invention.

### DETAILED DESCRIPTION

In the present specification, an expression used in the singular encompasses the expression of the plural, unless it has a clearly different meaning in the context. In the present specification, terms such as “comprising” or “including,” etc., should not be interpreted as meaning that all of the elements or operations are necessarily included. That is, some of the elements or operations may not be included, while other additional elements or operations may be further included. Also, terms such as “unit,” “module,” etc., as used in the present specification may refer to a part for processing at least one function or action and may be implemented as hardware, software, or a combination of hardware and software.

The invention relates to holographic data storage system and method using a modulation code technique to enhance a performance of the holographic data storage system. The modulation code technique of the invention indicates a 8/10 2D modulation code technique which modulates every input data (information sequence) having 8 bits to a (5×2) 2D output array, i.e. a codeword having 10 pixels. Serious interference may be removed by using the modulation code technique.

Hereinafter, various embodiments of the invention will be described in detail with reference to accompanying drawings.

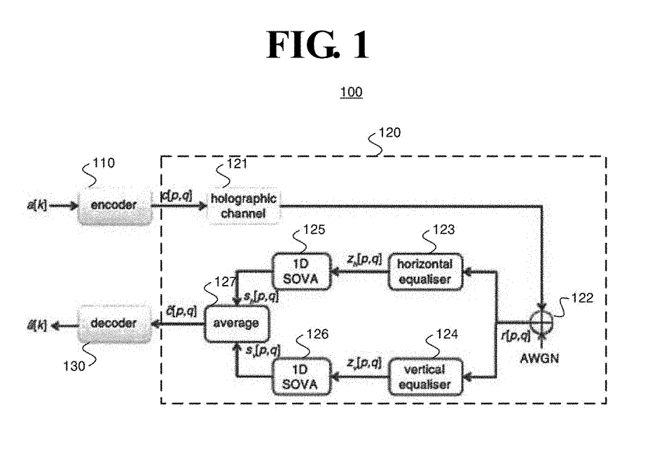

FIG. 1 is a view illustrating schematically a holographic data storage system HDS using the modulation code technique according to one embodiment of the invention.

In FIG. 1, a holographic data storage system 100 of the present embodiment includes an encoder 110, a storage unit 120 and a decoder 130.

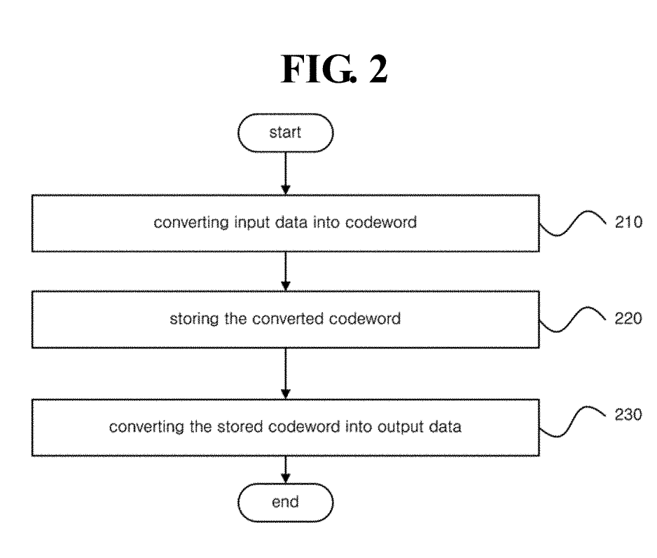

FIG. 2 is a flowchart illustrating a holographic data storage method according to one embodiment of the invention. Here, the holographic data storage method may be performed by a device including a processor.

Hereinafter, functions of elements and an operation of the invention will be described in detail.

In a step of 210, the encoder 110 converts input data into a codeword.

In a step of 220, the storage unit 120 stores the converted codeword. The storage unit 120 includes a holographic channel 121, an adder 122, a horizontal equalizer 123, a vertical equalizer 124, two soft output viterbi algorithms SOVAs 125 and 126 and an average calculation unit 127.

In a step of 230, the decoder 130 converts the stored codeword into output data.

Hereinafter, the encoder 110 of the present embodiment will be described in detail.

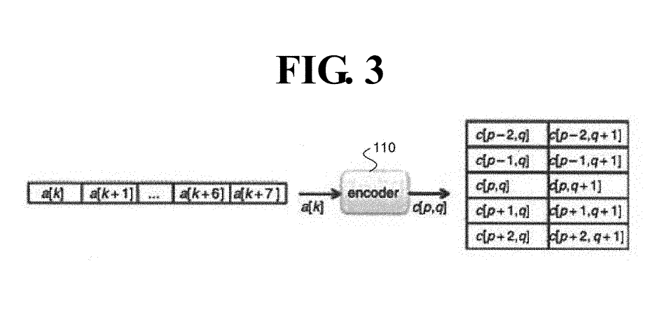

FIG. 3 is a view illustrating a concept of an operation of the encoder according to one embodiment of the invention.

In FIG. 3, the encoder 110 converts a sequence having 8 bits as user data into a codeword (array structure) having 10 bits in a (5×2) matrix. The converted codeword (2D array) is sequentially arranged in a page.

Here, a first column of the codeword (2D array) in the (5×2) matrix may be expressed as following vector c₅.

c₅≡[c[p−2,q]c[p−1,q]c[p,q]c[p+1,q]c[p+2,q]]^{T} [Equation 1]

Here, c₅ includes 5 bits, and thus total 32 patterns exist.

On the other hand, in the event that one bit placed at a center is surrounded by adjacent bits having logic opposed to logic of the one bit, detection error may occur to the one bit placed at the center in high probability. Accordingly, the encoder 110 determines three bits c[p−1, q], c[p, q] and c[p+1, q] placed at a center of the first column of the codeword in the (5×2) matrix.

In one embodiment, the encoder 110 does not arrange “1, 0, 1” to “0, 1, 0” at three bits (c[p−1, q]T, c[p, q] and c[p+1, q]) of a center of the vector c₅ corresponding to the first column of the codeword. That is, the vector c₅ is determined not to have a pattern [X, 0, 1, 0, X]^{T} or a pattern [X, 1, 0, 1, X]^{T}. Here, X equals to 0 or 1.

Briefly, the vector c₅ having 5 bits includes total 32 patterns. However, since the pattern [X, 0, 1, 0, X]^{T} or the pattern [X, 1, 0, 1, X]^{T} is not used, the encoder 110 may use 24 patterns.

Next, the 24 patterns may be divided into three groups as shown in table 1.

TABLE 1

| | group 1 | | group 2 | | group 3 | |
|---|---|---|---|---|---|---|
| c[p − 2, q] | X | X | 1 | 0 | X | X |
| c[p − 1, q] | 0 | 1 | 0 | 1 | 0 | 1 |
| c[p, q] | 0 | 1 | 1 | 0 | 0 | 1 |
| c[p + 1, q] | 1 | 0 | 1 | 0 | 0 | 1 |
| c[p + 2, q] | 0 | 1 | X | X | X | X |

Referring to Table 1, a first group includes a pattern [X, 0, 0, 1, 0]^{T} and a pattern [X, 1, 10, 1]^{T}, and brings out ISI at a lower part. A second group includes a pattern [1, 0, 1, 1, X]^{T} and a pattern [0, 1, 0, 0, X]^{T}, and occurs ISI at an upper part. Accordingly, the encoder 110 may not use 8 patterns in the first group and the second group.

A third group includes a pattern [X, 0, 0, 0, X]^{T} and a pattern [X, 1, 1, 1, X]^{T}, and little occurs ISI. Accordingly, the encoder 110 may use 8 patterns included in the third group. The encoder 110 may use a pattern [X, 0, 0, 1, 1]^{T} and a pattern [X, 1, 10, 0]^{T}, and a pattern [1, 1, 0, 0, X]^{T} and a pattern [1, 1, 0, 0, X]^{T}, wherein the patterns do not included in the first group and the second group. Thus, the encoder 110 may use total 16 patterns.

On the other hand, the same operation as of the encoder 110 may be applied to a second column of the codeword in the (5×2) matrix, and so the encoder 110 may use 16 patterns. Accordingly, the encoder 110 may use 256 patterns about the codeword in the (5×2) matrix.

Shortly, each of the first column and the second column of the (5×2) matrix has 32 patterns. The encoder 110 may not use the pattern [X, 1, 0, 1, X]^{T} and the pattern [X, 0, 1, 0, X]^{T} in the conversion of the codeword, wherein X equals to 0 or 1. The encoder 110 may not use the pattern [X, 0, 0, 1, 0]^{T} and the pattern [X, 1, 1, 0, 1]^{T} in the conversion of the codeword. Additionally, the encoder 110 may not use the pattern [1, 0, 1, 1, X]^{T} and the pattern [0, 1, 0, 0, X]^{T} in the conversion of the codeword.

That is, the encoder 110 may use 16 patterns of 32 patterns. The 16 patterns may include a pattern [0, 0, 0, 0, 0]^{T}, a pattern [0, 0, 0, 0, 1]^{T}, a pattern [0, 0, 0, 1, 1]^{T}, a pattern [0, 0, 1, 1, 0]^{T}, a pattern [0, 0, 1, 1, 1]^{T}, a pattern [0, 1, 1, 0, 0]^{T}, a pattern [0, 1, 1, 1, 0]^{T}, a pattern [0, 1, 1, 1, 1]^{T}, a pattern [1, 0, 0, 0, 0]^{T}, a pattern [1, 0, 0, 0, 1]^{T}, a pattern [1, 0, 0, 1, 1]^{T}, a pattern [1, 1, 0, 0, 0]^{T}, a pattern [1, 1, 0, 0, 1]^{T}, a pattern [1, 1, 1, 0, 0]^{T}, a pattern [1, 1, 1, 1, 0]^{T} and a pattern [1, 1, 1, 1, 1]^{T}.

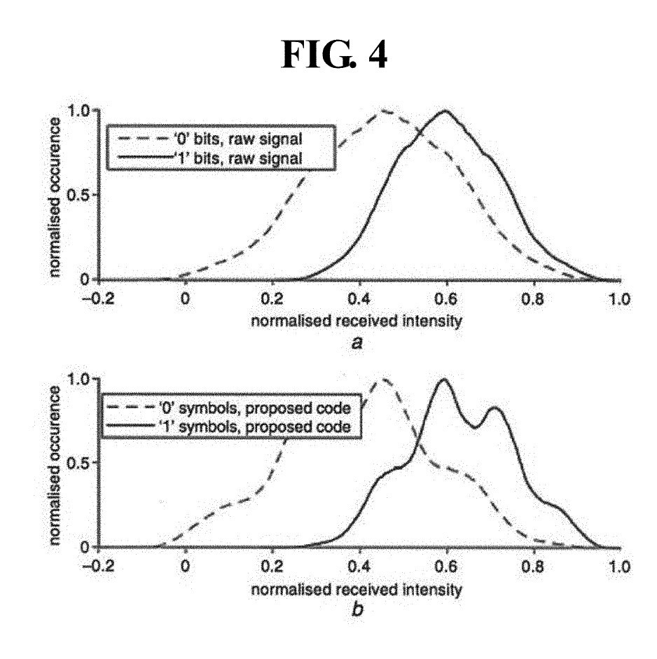

Hereinafter, a simulation result of the holographic data storage system and method of the invention will be described in detail with reference to accompanying drawings FIG. 4 to FIG. 6.

Firstly, a HDS channel is simulated by using a discrete point spread function which is expressed with following equation 2.

$$h [ p , q ] = {\int }_{q - 1 / 2}^{q + 1 / 2} {\int }_{p - 1 / 2}^{p + 1 / 2} \frac{1}{{σ}_{b}^{2}} {sinc}^{2} ( \frac{x - {m}_{x}}{{σ}_{b}} , \frac{y - {m}_{y}}{{σ}_{b}} ) dxdy \qquad [ Equation 2 ]$$

Here, σ_{b} means a grade of a blur of a resultant diffracted signal, and mₓ and m_{y} indicate misalignments of an x axis and a y axis, respectively. A linear fill factor of a charge coupled device may be 1. A decoded signal is delivered with additional white Gaussian noise AWGN through a hologram channel. A readback signal r[p,q] of a channel output terminal is equalized so that response is identical to response type of desired part. An output of an equalizer passes through a viterbi algorithm channel detector of 2D soft output to estimate a symbol transmitted with highest possibility. Finally, original information is searched by using a provided decoding method.

A performance of the holographic data storage system according to the modulation code technique of the invention is considered through a histogram of a received intensity. (a) in FIG. 4 illustrates a histogram of a received intensity when a user data bit in a holographic storage medium is a raw signal not encoded. In (a) in FIG. 4, much overlap exists between written bits. This means that a HDS system has an effect of 2D ISI. If the modulation code technique of the invention is applied, an overlap area sharply reduces. This is shown in (b) in FIG. 4. As a result, the modulation code technique of the invention efficiently reduces the 2D interference.

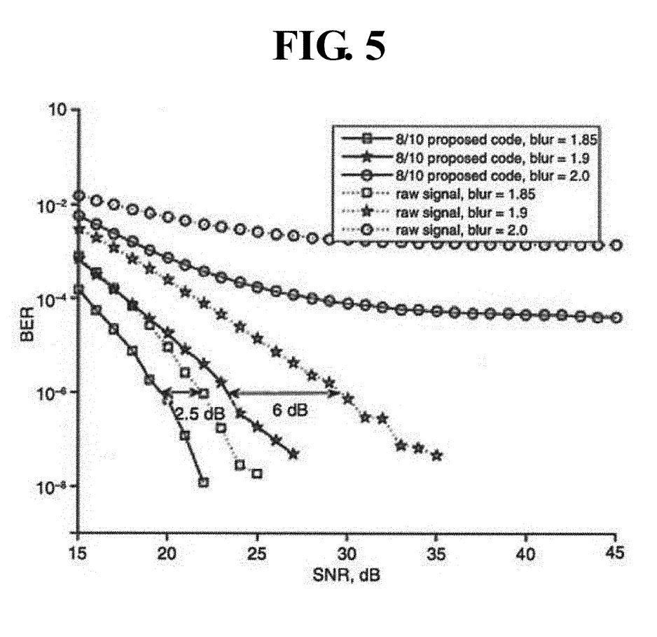

FIG. 5 is a view illustrating a BER performance of the modulation code technique of the invention compared to the raw signal not coded under an effect of the grade of the blur. 100 pages having (1024×1024) bits written for the simulation exist. Referring to FIG. 5, it is verified that the performance of the holographic data storage system when the modulation code technique of the invention is used is excellent compared with the other techniques. For example, in (10-6) BER, the modulation code technique may have a gain of approximately 2.5 dB. Furthermore, it is verified that the modulation code technique of the invention enhances the performance of a holographic data storage system by approximately 6 dB.

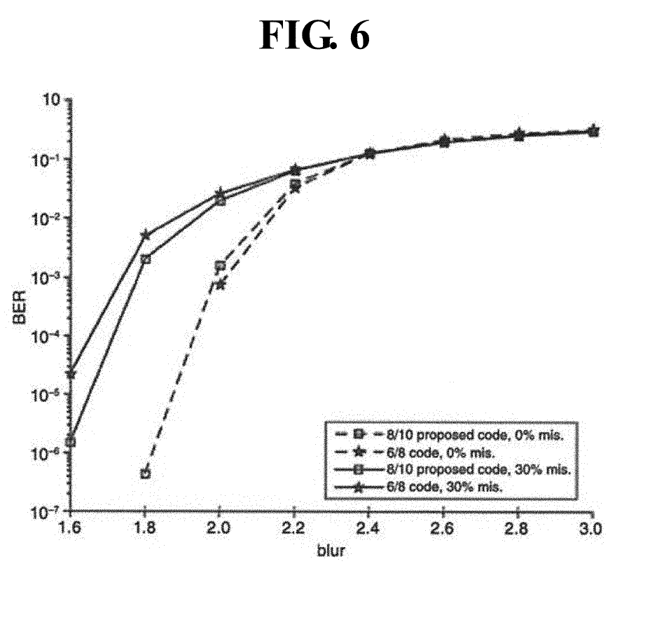

On the other hand, a 6/8 modulation code technique has been provided in recent (in 2-D non-isolated pixel 6/8 modulation code, IEEE Trans). The modulation code technique includes a codeword where two adjacent bits are expressed with the same symbol. This assures removal of an isolated pattern while data is written in the HDS system. To synthetically evaluate the performance, the modulation code technique of the invention and the 6/8 modulation code technique are compared in view of BER. This is shown in FIG. 6. Referring to FIG. 6, the modulation code techniques have very similar performance in the event that the grade of the blur is the same as or smaller than 2.2. However, the modulation code technique of the invention is more effective under misalignment. That is, it may be verified that the modulation code technique of the invention is less affected under the misalignment.

Also, the technical features described above can be implemented in the form of program instructions that may be performed using various computer means and can be recorded in a computer-readable medium. Such a computer-readable medium can include program instructions, data files, data structures, etc., alone or in combination. The program instructions recorded on the medium can be designed and configured specifically for the present invention or can be a type of medium known to and used by the skilled person in the field of computer software. Examples of a computer-readable medium may include magnetic media such as hard disks, floppy disks, magnetic tapes, etc., optical media such as CD-ROM's, DVD's, etc., magneto-optical media such as floptical disks, etc., and hardware devices such as ROM, RAM, flash memory, etc. Examples of the program of instructions may include not only machine language codes produced by a compiler but also high-level language codes that can be executed by a computer through the use of an interpreter, etc. The hardware mentioned above can be made to operate as one or more software modules that perform the actions of the embodiments of the invention, and vice versa.

The embodiments of the invention described above are disclosed only for illustrative purposes. A person having ordinary skill in the art would be able to make various modifications, alterations, and additions without departing from the spirit and scope of the invention, but it is to be appreciated that such modifications, alterations, and additions are encompassed by the scope of claims set forth below.

1. A holographic data storage system comprising:
an encoder configured to convert input data into a codeword;
a storage unit configured to store the converted codeword; and
a decoder configured to convert the stored codeword into output data,
wherein the encoder converts the input data having 8 bits into the codeword in (5×2) matrix.

2. The holographic data storage system of claim 1, wherein each of a first column and a second column of the (5×2) matrix has 32 patterns,
and wherein the encoder does not use a pattern [X, 1, 0, 1, X]^{T} and a pattern [X, 0, 1, 0, X]^{T} in the conversion of the codeword.

3. The holographic data storage system of claim 2, wherein the encoder does not use a pattern [X, 0, 0, 1, 0]^{T} and a pattern [X, 1, 1, 0, 1]^{T} in the conversion of the codeword.

4. The holographic data storage system of claim 3, wherein the encoder does not use a pattern [1, 0, 1, 1, X]^{T} and a pattern [0, 1, 0, 0, X]^{T} in the conversion of the codeword.

5. The holographic data storage system of claim 1, wherein each of a first column and a second column of the (5×2) matrix has 32 patterns and the encoder uses 16 patterns of the 32 patterns,
and wherein the 16 patterns include a pattern [0, 0, 0, 0, 0]^{T}, a pattern [0, 0, 0, 0, 1]^{T}, a pattern [0, 0, 0, 1, 1]^{T}, a pattern [0, 0, 1, 1, 0]^{T}, a pattern [0, 0, 1, 1, 1]^{T}, a pattern [0, 1, 1, 0, 0]^{T}, a pattern [0, 1, 1, 1, 0]^{T}, a pattern [0, 1, 1, 1, 1]^{T}, a pattern [1, 0, 0, 0, 0]^{T}, a pattern [1, 0, 0, 0, 1]^{T}, a pattern [1, 0, 0, 1, 1]^{T}, a pattern [1, 1, 0, 0, 0]^{T}, a pattern [1, 1, 0, 0, 1]^{T}, a pattern [1, 1, 1, 0, 0]^{T}, a pattern [1, 1, 1, 1, 0]^{T} and a pattern [1, 1, 1, 1, 1]^{T}.

6. A holographic data storage method performed by a processor, the method comprising:
an encoding step of converting input data into a codeword;
a storage step of storing the converted codeword; and
a decoding step of converting the stored codeword into output data,
wherein the encoding step includes converting the input data having 8 bits into the codeword in (5×2) matrix.

7. The holographic data storage method of claim 6, wherein each of a first column and a second column of the (5×2) matrix has 32 patterns, the encoder uses 16 patterns of the 32 patterns,
and wherein the 16 patterns include a pattern [0, 0, 0, 0, 0]^{T} a pattern [0, 0, 0, 0, 1]^{T}, a pattern [0, 0, 0, 1, 1]^{T}, a pattern [0, 0, 1, 1, 0]^{T}, a pattern [0, 0, 1, 1, 1]^{T}, a pattern [0, 1, 1, 0, 0]^{T}, a pattern [0, 1, 1, 1, 0]^{T}, a pattern [0, 1, 1, 1, 1]^{T}, a pattern [1, 0, 0, 0, 0]^{T}, a pattern [1, 0, 0, 0, 1]^{T}, a pattern [1, 0, 0, 1, 1]^{T}, a pattern [1, 1, 0, 0, 0]^{T}, a pattern [1, 1, 0, 0, 1]^{T}, a pattern [1, 1, 1, 0, 0]^{T}, a pattern [1, 1, 1, 1, 0]^{T} and a pattern [1, 1, 1, 1, 1]^{T}.
